(19) United States
(12) Patent Application Publication
(10) Pub. No.: US 2019/0221403 A1
(43) Pub. Date: Jul. 18, 2019

(54) PLASMA PROCESSING APPARATUS INCLUDING SHOWER HEAD WITH SUB-GAS PORTS AND RELATED SHOWER HEADS

(71) Applicant: Samsung Electronics Co., Ltd., Suwon-si (KR)

(72) Inventors: Seul Ha Myung, Hwaseong-si (KR); Hyo Sung Kim, Hwaseong-si (KR); Min Joon Park, Hwaseong-si (KR); Kyung Hoon Lee, Hwaseong-si (KR); Jae Hyun Lee, Hwaseong-si (KR)

(21) Appl. No.: 16/011,095

(22) Filed: Jun. 18, 2018

(30) Foreign Application Priority Data
Jan. 15, 2018 (KR) 10-2018-0004891

(51) Int. Cl. H01J 37/32; C23C 16/455; H01L 21/683

(52) U.S. Cl. CPC H01J 37/32449; C23C 16/45565; H01J 37/32458; H01J 37/32724; H01L 21/6831

(57) ABSTRACT

A plasma processing apparatus can include a process chamber and a susceptor in a lower portion of the process chamber. A chuck can be on the susceptor, where the chuck can include an upper surface configured to mount a wafer thereon. A shower head can include a plurality of first regions including gas ports and including a plurality of gas supply pipes separately communicating with the first regions and configured to independently supply a process gas into the process chamber toward the upper surface of the chuck, where each of the gas ports in the first regions includes a plurality of sub-gas ports. A process gas supplier can be configured to supply the process gas to the gas supply pipes and a control unit configured to independently control amounts of the process gas supplied to the gas supply pipes.

### CROSS-REFERENCE TO RELATED APPLICATION

This U.S. non-provisional patent application claims priority under 35 U.S.C. § 119 to and the benefit of Korean Patent Application No. 10-2018-0004891, filed on Jan. 15, 2018, in the Korean Intellectual Property Office (KIPO), the disclosure of which is incorporated herein by reference in its entirety.

### BACKGROUND

The present inventive concept relates to a plasma processing apparatus including gas supply devices or a shower head having independently controlled multiple regions. In a semiconductor fabrication process, specific materials can be stacked in a certain pattern on a wafer or a specific region may be etched. Etching processes are classified into a dry etching process and a wet etching process, and plasma etching is a type of dry etching. In a plasma etching process, an etch-target layer is etched by using plasma ions or radicals generated by spraying a process gas on a wafer from a shower head. However, due to the minute processes and the increasing wafer size resulting from integration of semiconductors, it may be difficult to ensure the yield of wafers (e.g., edge regions).

### SUMMARY

In some embodiments, a plasma processing apparatus can include a process chamber and a susceptor in a lower portion of the process chamber. A chuck can be on the susceptor, where the chuck can include an upper surface configured to mount a wafer thereon. A shower head can include a plurality of first regions including gas ports and including a plurality of gas supply pipes separately communicating with the first regions and configured to independently supply a process gas into the process chamber toward the upper surface of the chuck, where each of the gas ports in the first regions includes a plurality of sub-gas ports. A process gas supplier can be configured to supply the process gas to the gas supply pipes and a control unit configured to independently control amounts of the process gas supplied to the gas supply pipes.

In some embodiments, a plasma processing apparatus can include a process chamber and a susceptor in a lower portion of the process chamber. A chuck can be on the susceptor, where the chuck can include an upper surface which is configured to mount a wafer thereon. A shower head can be configured to spray a process gas into the process chamber toward the upper surface. A plurality of gas supply devices can be on a side surface of the chuck and have gas ports. A first process gas supplier can be configured to supply the process gas to the shower head. A second process gas supplier can be configured to supply the process gas to the gas supply devices and a control unit can be configured to independently control respective amounts of the process gas supplied to the gas supply devices.

In some embodiments, a shower head can be configured to spray a process gas into a process chamber, where the shower head can include a plurality of first regions having gas ports and a plurality of gas supply pipes separately communicating with the first regions and can be configured to independently supply the process gas to the gas ports, where each of the gas ports in the first regions can include a plurality of sub-gas ports.

### BRIEF DESCRIPTION OF THE DRAWINGS

The above and other objects, features, and advantages of the present inventive concept will become more apparent to those of ordinary skill in the art by describing exemplary embodiments thereof in detail with reference to the accompanying drawings, in which:

FIG. 1 is a diagram showing a structure of a plasma processing apparatus according to an exemplary embodiment of the present inventive concept;

FIG. 2A is a bottom-up view of a shower head according to an exemplary embodiment of the present inventive concept;

FIG. 2B is a cross-sectional view taken along cutoff line I-I′ of a gas port shown in FIG. 2A;

FIG. 2C is a cross-sectional view taken along cutoff line I-I′ of the gas port according to another exemplary embodiment of the present inventive concept;

FIG. 3 is a bottom-up view of a shower head according to an exemplary embodiment of the present inventive concept;

FIG. 4 is a bottom-up view of a shower head according to an exemplary embodiment of the present inventive concept;

FIG. 5A is a bottom-up view of a shower head according to an exemplary embodiment of the present inventive concept;

FIG. 5B is a cross-sectional view taken along cutoff line II-II′ of a gas port shown in FIG. 5A;

FIGS. 6A and 6B are enlarged views of a gas port according to another exemplary embodiment of the present inventive concept;

FIG. 6C is a cross-sectional view taken along cutoff line III-III′ of a gas port shown in FIG. 6B;

FIG. 7 is a top-down view of gas supply devices according to an exemplary embodiment of the present inventive concept;

FIG. 8 a top-down view of gas supply devices according to another exemplary embodiment of the present inventive concept; and

FIG. 9 is a diagram showing a structure of a plasma processing apparatus according to an exemplary embodiment of the present inventive concept.

### DETAILED DESCRIPTION OF EXEMPLARY EMBODIMENTS

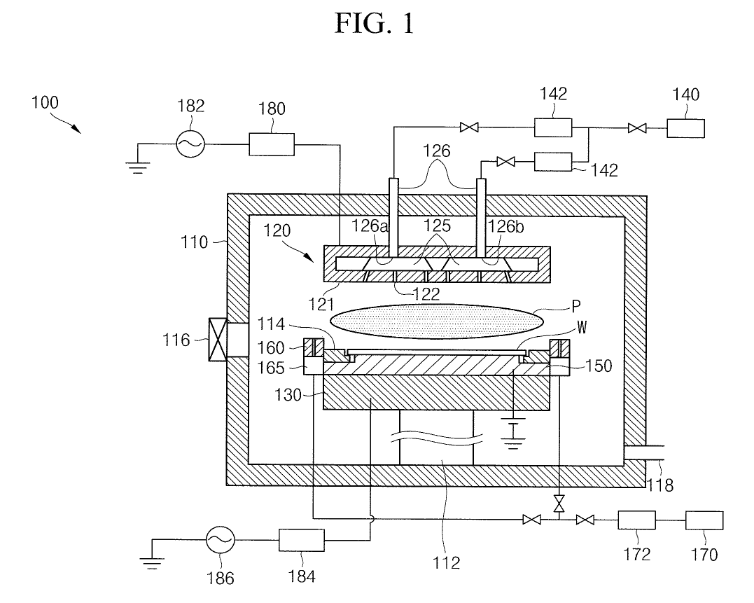

FIG. 1 is a diagram showing a structure of a plasma processing apparatus 100 according to an exemplary embodiment of the present inventive concept.

Referring to FIG. 1, the plasma processing apparatus 100 of the present inventive concept may be a capacitively coupled plasma etching apparatus. As an example, the plasma processing apparatus 100 may be a dual frequency capacitively coupled plasma etching apparatus. The plasma processing apparatus 100 may include a process chamber 110, a shower head 120, a susceptor 130, a first process gas supplier 140, a chuck 150, gas supply devices 160, a second process gas supplier 170. The plasma processing apparatus 100 may generate plasma P from a process gas introduced from the first process gas supplier 140 and the second process gas supplier 170 into the process chamber 110.

The process chamber 110 may provide an airtight space therein so that an etching process may be performed on a wafer W. The process chamber 110 may have a cylindrical shape or a rectangular barrel shape, but is not limited thereto. The process chamber 110 may be formed of a metal, for example, aluminum or stainless steel. The process chamber 110 may be grounded.

The process chamber 110 may include the shower head 120 and the susceptor 130. The shower head 120 may be positioned in an upper portion of the process chamber 110, and the susceptor 130 may be positioned in a lower portion of the process chamber 110. The process chamber 110 may further include a supporting stand 112, an edge ring 114, a gate valve 116, and an exhaust port 118. The supporting stand 112 may be positioned in the lower portion of the process chamber 110 and formed to support the susceptor 130.

The edge ring 114 is on the chuck 150, and the edge ring 114 has a greater diameter than the wafer W and may be positioned around an edge of the wafer W. A part of the edge ring 114 may support a lower surface of the edge of the wafer W.

The edge ring 114 may be formed of various materials according to the type of etch-target layer of the wafer W. As an example, for the edge ring 114, quartz may be used in a poly etch process, silicon (Si) may be used in an oxide etch process, and ceramic alumina may be used. Alternatively, the edge ring 114 may be formed of Teflon.

The edge ring 114 may prevent diffusion of the plasma P in the process chamber 110 and concentrate the plasma P on the wafer W to be etched. Also, the edge ring 114 may fix the position of the wafer W placed on the chuck 150. When the edge ring is formed of ceramic or Teflon, it is possible to suppress generation of a polymer, which is a byproduct generated from the wafer W in a dry etching process and to suppress accumulation of the polymer on the edge of the wafer W.

The gate valve 116 may be on a sidewall of the process chamber 110. The wafer W is loaded into and unloaded from the process chamber 110 through the gate valve 116. The process chamber 110 may further include the exhaust port 118 for discharging the process gas or reaction byproducts. The exhaust port 118 may be in the lower portion of the process chamber 110. The exhaust port 118 may be connected to a vacuum pump, and a pressure control valve, a flow control valve, etc. may be installed in the exhaust port 118. The vacuum pump may discharge the process gas, etching reactants, or the like in the process chamber 110 to the outside of the process chamber 110 by decompressing the process chamber 110.

The shower head 120 may include a shower plate 121, a housing 125, and gas supply pipes 126. The shower head 120 may be formed in the upper portion of the process chamber 110 and may serve as an upper electrode. Also, the shower head 120 may be supplied with the process gas from the first process gas supplier 140 and provide the process gas to the process chamber 110. For example, the shower head 120 may spray the process gas on an upper portion of the wafer W. The shower plate 121 may be on a lower surface of the shower head 120. One side of the housing 125 may come in contact with an upper portion of the shower plate 121, and the other side of the housing 125 may come in contact with outlets 126a and 126b of the gas supply pipes 126. The housing 125 may include a gas channel therein. The gas supply pipes 126 may guide the process gas coming from the first process gas supplier 140 into the process chamber 110.

The susceptor 130 may be positioned in the lower portion of the process chamber 110 and disposed under the chuck 150 and on the supporting stand 112. The susceptor 130 may serve as a lower electrode. The susceptor 130 may include a heater for heating the wafer W up to a temperature used for a process. In the susceptor 130, a refrigerant channel in which a refrigerant flows may be formed to control a temperature of the wafer W during plasma processing. A gas channel in which a backside gas flows may be between a lower surface of the wafer W and an upper surface of the chuck 150 to distribute a temperature of the susceptor 130 to the wafer W.

The first process gas supplier 140 may supply the process gas to the process chamber 110. For example, the process gas may be supplied from the first process gas supplier 140 to the gas supply pipes 126 through mass flow controllers 142 and valves. The mass flow controllers 142 may adjust a supplied amount of the process gas. The valves may control a supplied amount of gas in an on/off manner. For example, the valves may be formed between the mass flow controllers 142 and the gas supply pipes 126 and may control whether to supply the process gas to the gas supply pipes 126.

As an example of the process gas, chlorine or fluorine may be included. Also, the process gas may include NF3, C2F6, CF4, COS, SF6, Cl2, BCl3, C2HF5, and the like. Besides, the process gas may further include all or some of inert gases, such as N2, Ar, He, etc., H2, and O2.

The chuck 150 may be on the susceptor 130 and may also be integral with the susceptor 130. The chuck 150 may have a disk shape. The wafer W having an etch-target layer may be mounted on the upper surface of the chuck 150. The etch-target layer may be an epitaxial layer, a doped polysilicon layer, a metal silicide layer, a metal layer, a silicon oxide layer, a silicon nitride layer, a silicon oxynitride layer, a crystalline silicon layer, an amorphous silicon layer, or a silicon Ge layer. The etch-target layer may be etched by plasma ions or radicals.

The chuck 150 may be an electrostatic chuck (ESC) that fixes the wafer W by using the electrostatic principle. For example, an ESC may be formed of a dielectric including an electrode therein. When a high voltage direct current (DC) power is applied to the electrode, the wafer W may be adsorbed and fixed by electrostatic force. In FIG. 1, the chuck 150 is shown as an ESC, but the chuck 150 is not limited thereto. The chuck 150 may include any fixed chuck, such as a chuck that fixes the wafer W in a mechanical clamping manner, a vacuum chuck that adsorbs and supports the wafer W via vacuum pressure, and the like.

The gas supply devices 160 may be formed on a side surface of the chuck 150. A plurality of gas supply devices 160 may be formed along the circumference of the chuck 150. The gas supply devices 160 may provide a process gas to the space between the shower head 120 and the wafer W. The gas supply devices 160 may spray the process gas vertically upward. The gas supply devices 160 may control etching of an edge region of the wafer W by adjusting generation of the plasma P in a space corresponding to the edge of the wafer W. The gas supply devices 160 may supply the process gas at the same time as or separately from the shower head 120.

The gas supply devices 160 may include elevation adjustment devices 165 thereunder. The elevation adjustment devices 165 may move the gas supply devices 160 up or down. The elevation adjustment devices 165 may move the gas supply devices 160 by using a motor, a piezoelectric element, or a pneumatic cylinder.

The second process gas supplier 170 may supply the process gas to the gas supply devices 160 through a mass flow controller 172. The process gas supplied by the second process gas supplier 170 may be the same as the process gas supplied by the first process gas supplier 140. The mass flow controller 172 may adjust a supplied amount of the process gas. A valve may control a supplied amount of gas in an on/off manner.

The first matcher 180 may match an impedance of a first high-frequency power source 182 to an impedance of the process chamber 110. The first high-frequency power source 182 may be electrically connected to the shower head 120 through the first matcher 180. The first high-frequency power source 182 may output a high-frequency wave of a frequency (e.g., 60 MHz) suitable for ionizing the process gas in the process chamber 110 to generate the plasma P. The first high-frequency power source 182 may efficiently transfer power to the plasma P due to the first matcher 180.

The second matcher 184 may match an impedance of a second high-frequency power source 186 to the impedance of the process chamber 110. The second high-frequency power source 186 may be electrically connected to the susceptor 130 through the second matcher 184. The second high-frequency power source 186 may output a biasing power and output a high-frequency wave of a frequency suitable for controlling ionization energy applied to the wafer W. The second high-frequency power source 186 may efficiently transfer power to the plasma P due to the second matcher 184.

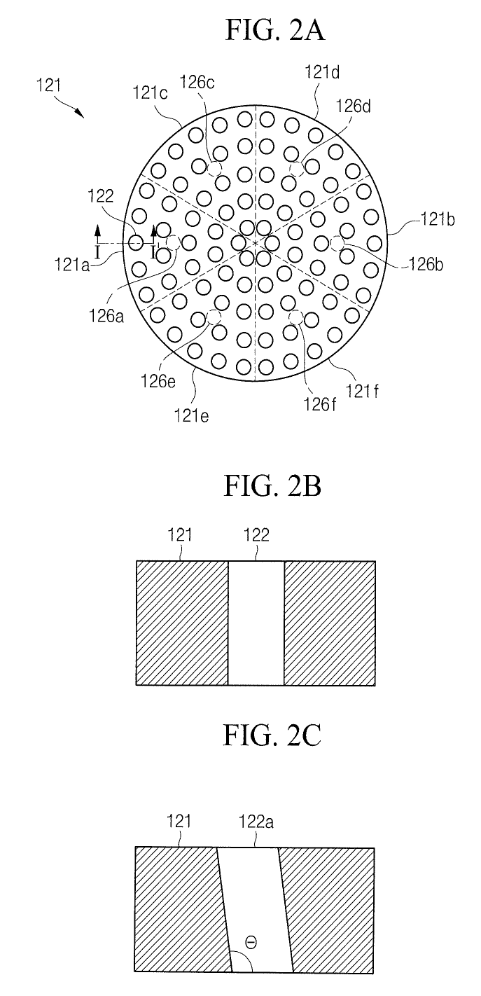

FIG. 2A is a bottom-up view of the shower head 120 according to an exemplary embodiment of the present inventive concept. FIG. 2B is a cross-sectional view taken along line I-I′ of a gas port shown in FIG. 2A. FIG. 2C is a cross-sectional view taken along line I-I′ of the gas port according to another exemplary embodiment of the present inventive concept.

Referring to FIGS. 1 and 2A, the shower plate 121 may be on the lower surface of the shower head 120. Here, the lower surface of the shower head 120 may denote a direction toward the wafer W. The shower plate 121 may include first regions 121a, 121b, 121c, 121d, 121e, and 121f and gas ports 122. The shower plate 121 may have a disk shape. A size of the gas ports 122 may be 5 mm or less. However, the size is not limited thereto.

The gas ports 122 in the shower plate 121 may be disposed in concentric circles with respect to a center of the shower plate 121. The shower plate 121 may evenly spray the process gas so that the etch-target layer is evenly etched across the surface of the wafer W. Also, the shower plate 121 may control an amount of the process gas supplied to the edge of the wafer W on which distribution is unevenly made.

The shower plate 121 may be divided into the fan-shaped first regions 121a, 121b, 121c, 121d, 121e, and 121f with respect to the center of the shower plate 121. The respective first regions 121a, 121b, 121c, 121d, 121e, and 121f may communicate with the different gas supply pipes 126. For example, the first region 121amay communicate with the outlet 126a of the gas supply pipes 126. The first region 121b may communicate with the outlet 126b of the gas supply pipes 126. The other first regions 121c, 121d, 121e, and 121f may communicate with outlets 126c, 126d, 126e, and 126f, respectively. In an exemplary embodiment of the present inventive concept, the shower plate 121 is divided into the six first regions, but may also be divided into a greater or lesser number of first regions.

The control unit may include the mass flow controllers 142 and valves. The process gas supplied to the respective first regions may be controlled by the control unit. For example, the mass flow controllers 142 may control amounts of gas independently supplied to the respective first regions. The valves may operate in an on/off manner, and independently control whether to supply the gas to the respective first regions. The valves may be piezo valves. An amount of the process gas supplied to at least one of the plurality of gas supply pipes 126 may be controlled by the control unit differently from the other gas supply pipes 126.

Referring to FIG. 2B, the gas ports 122 may extend in a vertical direction. Here, the vertical direction may denote a direction perpendicular to the wafer W. The gas ports 122 formed in the vertical direction may be disposed on the entire surface of the shower plate 121 so that the process gas is evenly sprayed.

Referring to FIG. 2C, gas ports 122a may be inclined outward relative to a vertical axis at a center of the shower head 120. As an example, a sidewall of the gas ports 122a may form an angle θ of 90 degrees or more with respect to a horizontal direction. The gas may be sprayed toward the edge region of the wafer W from the gas ports 122a inclined outward from the vertical axis at the center of the shower head 120. In this exemplary embodiment, θ is 90 degrees or more, but is not limited thereto. When the process gas supplied to the edge region of the wafer W is insufficient or abundant, it is possible to improve distribution of the process gas to the edge of the wafer Win an etching process by using the gas ports 122a inclined with respect to the vertical direction.

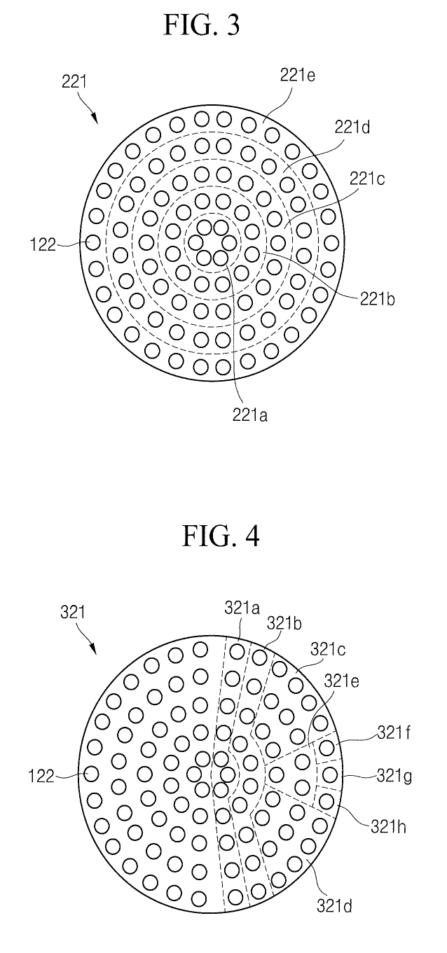

FIG. 3 is a bottom-up view of the shower head 120 according to an exemplary embodiment of the present inventive concept.

Referring to FIG. 3, a shower plate 221 may be divided into first regions 221a, 221b, 221c, 221d, and 221e having certain distances from a center of the shower plate 221. As an example, the first region 221amay be a circular region with respect to the center of the shower plate 221. The first region 221b may be positioned around a circumference of the first region 221aand may have a ring shape. The first region 221c may be positioned around a circumference of the first region 221b and may have a ring shape. The first region 221d may be positioned around a circumference of the first region 221c and may have a ring shape. The first region 221e may be positioned around a circumference of the first region 221d and may have a ring shape.

The respective first regions 221a, 221b, 221c, 221d, and 221e may communicate with the different gas supply pipes 126. Gas supply to the respective first regions 221a, 221b, 221c, 221d, and 221e may be independently controlled by the control unit including the mass flow controllers 142 and the valves. For example, the mass flow controllers 142 may independently control flow amounts of the respective first regions. Only a gas flow amount for the first region 221e at the outermost edge may be independently controlled, so that more or less of the process gas may be sprayed on the edge region of the wafer W compared to the center of the wafer W. According to the control method, it is possible to improve distribution at the edge of the wafer W. Also, the valves may control whether to supply the gas to the respective first regions.

FIG. 4 is a bottom-up view of the shower head 120 according to an exemplary embodiment of the present inventive concept.

Referring to FIG. 4, a right semicircle of a shower plate 321 may be divided into first regions 321a, 321b, 321c, 321d, 321e, 321f, 321g, and 321h. The first region 321amay be a region that radially extends from the center of the shower plate 321 and includes gas ports 122 leftmost in the right semicircle of the shower plate 321. The first region 321b may be a region that is formed only on the right of the first region 321aand radially extends. The first region 321e may be a fan-shaped region in the remaining region of the right semicircle, and each of the first regions 321f, 321g, and 321h may be a region that is positioned outside the first region 321e and includes one gas port 122. The first regions 321c and 321d may be regions other than those mentioned above. A left semicircle of the shower plate 321 may be divided in the same way as the right semicircle.

Supply of the process gas to the first regions 321a, 321b, 321c, 321d, 321e, 321f, 321g, and 321h may be independently controlled by the mass flow controllers 142 and the valves. Since the first regions 321aand 321b are formed in radially extending stick shapes, it is possible to control the process gas supplied to a corresponding stripe (or radial) portion of the wafer W. In another exemplary embodiment, the first regions 321aand 321b may be formed in horizontally extending stick shapes. Since each of the first regions 321f, 321g, and 321h includes one gas port 122, it is possible to control, in units of gas ports 122, a gas flow amount and whether to supply the gas.

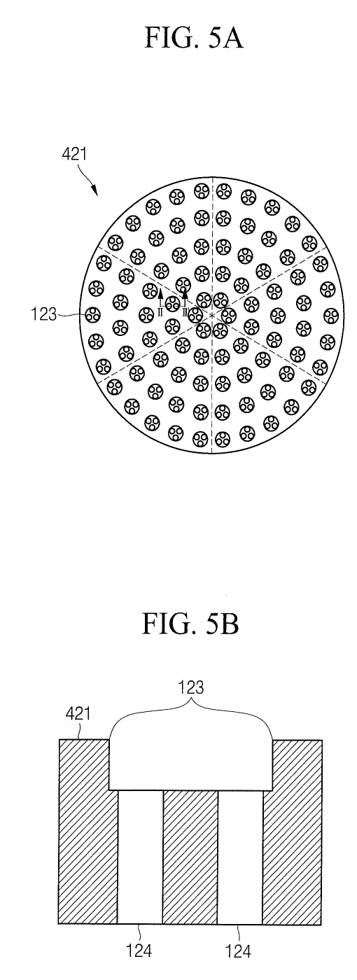

FIG. 5A is a bottom-up view of the shower head 120 according to an exemplary embodiment of the present inventive concept. FIG. 5B is a cross-sectional view taken along cutoff line II-II′ of a gas port 123 shown in FIG. 5A.

Referring to FIGS. 5A and 5B, a shower plate 421 may include gas ports 123. The gas ports 123 may include sub-gas ports 124. In an exemplary embodiment of the present inventive concept, three sub-gas ports 124 are formed in a gas port 123, but the number of sub-gas ports is not limited thereto. The sub-gas ports 124 may have the same diameter and may be disposed symmetrically with respect to a center of the gas port 123 so that the process gas supplied from the gas port 123 is evenly sprayed.

For example, when the gas port 123 has three sub-gas ports 124, the sub-gas ports 124 may be disposed to form an equilateral triangle with respect to the center of the gas port 123. In an exemplary embodiment, when the gas port 123 has four sub-gas ports 124, the sub-gas ports 124 may be disposed to form a square with respect to the gas port 123.

Flow amounts of the respective gas ports 123 may be independently controlled by the different mass flow controllers 142. Whether to supply the gas to the respective gas ports 123 may be controlled by different valves.

Referring back to FIG. 5B, the gas ports 123 may have recesses in the shower plate 421. In an exemplary embodiment, the gas ports 123 may only denote regions including the sub-gas ports 124 and do not have the recesses. The gas ports 123 may include the sub-gas ports 124 formed in the vertical direction. Whether to supply the gas to the respective sub-gas ports 124 may be controlled by different valves. The valves may be piezo valves. The sub-gas ports 124 may have a diameter of 5 mm or less.

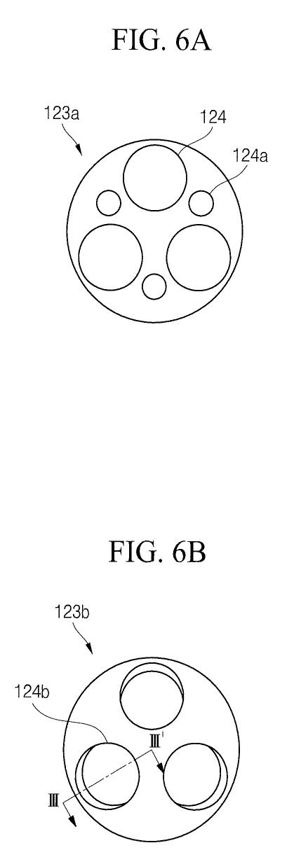

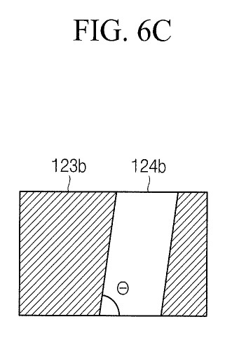

FIGS. 6A and 6B are partially enlarged views of gas ports 123a and 123b according to another exemplary embodiment of the present inventive concept.

FIG. 6C is a cross-sectional view taken along cutoff line of a sub-gas port 124b shown in FIG. 6B.

Referring to FIG. 6A, sub-gas ports 124 and 124a having different sizes may be formed in the gas port 123a. For example, the sub-gas ports 124a may have a smaller diameter than the sub-gas ports 124. The sub-gas ports 124 and 124a may be disposed symmetrically with respect to a center of the gas ports 123a so that the supplied gas is evenly sprayed.

In an exemplary embodiment, four or more sub-gas ports 124 and 124a may be formed in the gas port 123a, and the gas port 123a may further include a sub-gas port having a different size.

Referring to FIGS. 6B and 6C, the gas port 123b may include sub-gas ports 124b. The sub-gas ports 124b may be formed to be inclined outward from the vertical axis at the center of the shower head 120. As an example, the sub-gas ports 124b may be formed to be inclined at an angle θ with respect to the horizontal direction. Here, the vertical direction may denote a direction perpendicular to the wafer W. Some gas ports 124b of the gas port 123b may be formed in the vertical direction. When θ is less than 90 degrees, the process gas may be sprayed in a direction opposite to the center of the gas port 123b. It is possible to improve distribution by evenly supplying the process gas, which is sprayed out of the gas port 123b, to the edge region of the wafer W. In an exemplary embodiment, the sub-gas ports 124b may be formed at the angle θ of 90 degrees or more.

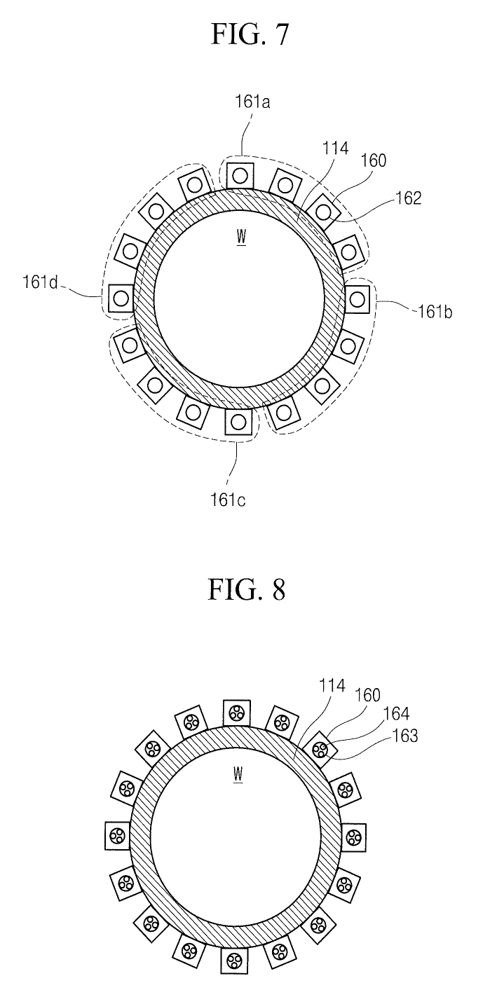

FIG. 7 is a top-down view of the gas supply devices 160 according to an exemplary embodiment of the present inventive concept.

Referring to FIGS. 1 and 7, the gas supply devices 160 may be formed on the side surface of the chuck 150. As seen from above, the gas supply devices 160 may be externally formed along a circumference of the edge ring 114. A plurality of gas supply devices 160 may be formed along the circumference of the chuck 150 and disposed symmetrically with respect to the center of the wafer W.

The gas supply devices 160 may be supplied with the process gas from the second process gas supplier 170 and supply the process gas into the process chamber 110. Flow amounts of the process gas supplied to the gas supply devices 160 may be controlled by a control unit including the mass flow controller 172 and valves. An amount of the process gas supplied to at least one of the plurality of gas supply devices 160 may be controlled by the control unit differently from the other gas supply devices 160.

The gas supply devices 160 may be divided into first regions 161a, 161b, 161c, and 161d. Each of the first regions 161a, 161b, 161c, and 161d may include four adjacent gas supply devices 160. In an exemplary embodiment, the gas supply devices 160 may be divided into a greater number of regions. The amounts of gas supplied to the respective first regions 161a, 161b, 161c, and 161d may be independently controlled by different mass flow controllers 172. Whether to supply the gas to the first regions 161a, 161b, 161c, and 161d may be controlled by the valves. In an exemplary embodiment, the respective gas supply devices 160 may be independently controlled.

The elevation adjustment devices 165 may be formed in the gas supply devices 160. The elevation adjustment devices 165 may move the gas supply devices 160 vertically up or down. The elevation adjustment devices 165 may be independently controlled according to the gas supply devices 160.

In the gas supply devices 160, gas ports 162 may be formed in the vertical direction or formed to be inclined from the vertical direction.

FIG. 8 a top-down view of the gas supply devices 160 according to another exemplary embodiment of the present inventive concept.

Referring to FIG. 8, the gas supply devices 160 may include gas ports 163, and the gas ports 163 may include a plurality of sub-gas ports 164. Although not shown in the drawing, a plurality of gas ports 163 may be included in each of the gas supply devices 160. The sub-gas ports 164 formed in the gas ports 163 may be disposed symmetrically with respect to centers of the gas ports 163. The sub-gas ports 164 of the gas ports 163 may have a certain diameter and may be formed to have different diameters. The respective sub-gas ports 164 may be independently controlled by valves. Diameters of the sub-gas ports 164 may be 5 mm or less. The valves may be piezo valves.

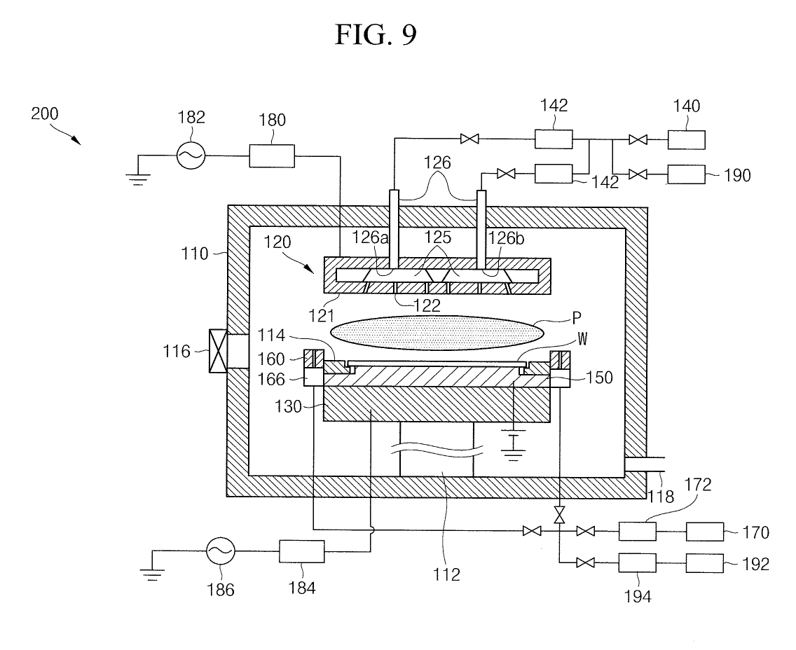

FIG. 9 is a conceptual diagram showing a structure of a plasma processing apparatus 200 according to an exemplary embodiment of the present inventive concept. Description of parts the same as those described above with reference to FIG. 1 may be omitted.

Referring to FIG. 9, a deposition gas supplier 190 may provide a deposition gas to a process chamber 110. The deposition gas supplier 190 may supply the deposition gas to gas supply pipes 126 through mass flow controllers 142 and valves. The deposition gas and a process gas may be alternately supplied into the process chamber 110. The mass flow controllers 142 may adjust a supplied amount of the deposition gas. The valves may control a supplied amount of deposition gas flow. The valves may control the gas flow amount in an on/off manner. The deposition gas may be C4F8, C4F6, CHF3, CH2F2, or a combination of one or more thereof.

An etching process in which the deposition gas and the process gas are supplied may be a Bosch process. For example, the Bosch process may involve etching an etch-target layer by supplying the process gas for a certain time and then forming a protection layer on an etched wall by supplying the deposition gas. When the process gas is supplied again, a bottom of the protection layer is etched by ions having an orientation in a vertically downward direction. Therefore, the etch-target layer on the wafer W is exposed, and an etching process proceeds again. Since ion impact is not applied to a sidewall of the protection layer, it is possible to prevent lateral etching. When the above process is repeated, it is possible to form a trench or a port having a high aspect ratio.

The gas supply devices 160 may further include heating means 166 thereunder. The heating means 166 may heat the gas supply devices 160 while the deposition gas is supplied into the process chamber 110. The heating means 166 may prevent gas ports 162 and 163 of the gas supply devices 160 from being blocked by the deposition gas. The heating means 166 may include elevation adjustment devices.

A purge gas supplier 192 may supply a purge gas to the gas supply devices 160 through a mass flow controller 194 and valves. The purge gas may include an inert gas such as N2 and the like. The purge gas supplier 192 may supply the purge gas to the gas supply devices 160 while the deposition gas is supplied into the process chamber 110. The purge gas may prevent the gas ports 162 and 163 of the gas supply devices 160 from being blocked by the deposition gas.

According to the exemplary embodiments of the present inventive concept, a shower head is divided into multiple regions such that gas flow amounts may be independently controlled by region.

According to the exemplary embodiments of the present inventive concept, gas supply devices are formed on a side surface of a chuck, and a gas may be directly supplied to an edge region of a wafer. Therefore, it is possible to improve distribution on the edge region of the wafer.

According to the exemplary embodiments of the present inventive concept, diameters and slopes of gas ports of a shower head and gas supply devices are selected so that the amount of gas supplied to a local region of a wafer may be controlled.

Although the exemplary embodiments of the present inventive concept have been described with reference to the accompanying drawings, those of ordinary skill in the art to which the present inventive concept pertains would appreciate that the present inventive concept may be implemented in other concrete forms without departing from the technical spirit and essential features thereof. The above-described embodiments should be regarded as exemplary rather than limiting in all aspects.

What is claimed:

1. A plasma processing apparatus comprising:
a process chamber;
a susceptor in a lower portion of the process chamber;
a chuck on the susceptor, the chuck including an upper surface configured to mount a wafer thereon;
a shower head including a plurality of first regions including gas ports and including a plurality of gas supply pipes separately communicating with the first regions and configured to independently supply a process gas into the process chamber toward the upper surface of the chuck, wherein each of the gas ports in the first regions includes a plurality of sub-gas ports;
a process gas supplier configured to supply the process gas to the gas supply pipes; and
a control unit configured to independently control amounts of the process gas supplied to the gas supply pipes.

2. The plasma processing apparatus of claim 1, wherein a first amount of the process gas supplied to at least one of the gas supply pipes differs from a second amount of the process gas supplied to other ones of the gas supply pipes.

3. The plasma processing apparatus of claim 1, wherein the first regions have a circular shape and a ring shape with respect to a center of the shower head.

4. The plasma processing apparatus of claim 1, wherein the first regions have a fan shape with respect to a center of the shower head.

5. The plasma processing apparatus of claim 1, wherein gas ports include sidewall that are inclined outward relative to a vertical axis at a center of the shower head.

6. The plasma processing apparatus of claim 1, wherein sub-gas ports of each of the gas ports have different diameters.

7. The plasma processing apparatus of claim 1, wherein the control unit includes a piezo valve.

8. The plasma processing apparatus of claim 1, wherein the gas ports have a diameter of 5 mm or less.

9. A plasma processing apparatus comprising:
a process chamber;
a susceptor in a lower portion of the process chamber;
a chuck on the susceptor, the chuck including an upper surface which is configured to mount a wafer thereon;
a shower head configured to spray a process gas into the process chamber toward the upper surface;
a plurality of gas supply devices on a side surface of the chuck and having gas ports;
a first process gas supplier configured to supply the process gas to the shower head;
a second process gas supplier configured to supply the process gas to the gas supply devices; and
a control unit configured to independently control respective amounts of the process gas supplied to the gas supply devices.

10. The plasma processing apparatus of claim 9, wherein each of the gas supply devices include at least two gas ports having different diameters.

11. The plasma processing apparatus of claim 9, wherein the gas supply devices include sidewalls of the gas ports that are inclined outward relative to a vertical axis at a center of the shower head.

12. The plasma processing apparatus of claim 9, wherein the gas supply devices further include elevation adjustment devices.

13. The plasma processing apparatus of claim 9, further comprising a deposition gas supplier configured to supply a deposition gas to the shower head,
wherein the first process gas supplier and the deposition gas supplier are configured to alternately supply the process gas and the deposition gas to the process chamber through the shower head.

14. The plasma processing apparatus of claim 13, wherein the gas supply devices further include heating means.

15. The plasma processing apparatus of claim 9, wherein the gas ports have a diameter of 5 mm or less.

16. The plasma processing apparatus of claim 9, wherein the control unit includes a piezo valve.

17. A shower head configured to spray a process gas into a process chamber, the shower head including a plurality of first regions having gas ports and a plurality of gas supply pipes separately communicating with the first regions and configured to independently supply the process gas to the gas ports, wherein each of the gas ports in the first regions includes a plurality of sub-gas ports.

18. The shower head of claim 17, wherein sidewalls of the gas ports are inclined outward relative to a vertical axis at a center of the shower head.

19. The shower head of claim 17, wherein the sub-gas ports have different diameters.

20. The shower head of claim 17, wherein the gas ports have a diameter of 5 mm or less.
